(19) United States
(12) Patent Application Publication
(10) Pub. No.: US 2025/0197561 A1
(43) Pub. Date: Jun. 19, 2025

(54) POLYMER, COMPOSITION, AND OPTOELECTRONIC DEVICE

(71) Applicants: Guangdong Juhua Research Institute of Advanced Display, Guangzhou (CN); TCL Technology Group Corporation, Huizhou (CN)

(72) Inventor: Congcong CAO, Guangzhou (CN)

(73) Assignees: Guangdong Juhua Research Institute of Advanced Display, Guangzhou (CN); TCL Technology Group Corporation, Huizhou (CN)

(21) Appl. No.: 18/982,743

(22) Filed: Dec. 16, 2024

(30) Foreign Application Priority Data
Dec. 15, 2023 (CN) 202311745725.9

(51) Int. Cl. C08G 61/12

(52) U.S. Cl. CPC C08G 61/126; C08G 2261/3221; C08G 2261/3223; C08G 2261/512; C08G 2261/91

(57) ABSTRACT

Disclosed in the present disclosure are a polymer, a composition, and an optoelectronic device. The polymer has a structure of formula (I), wherein n is any integer from 10 to 50, Ar₁ is selected from any one of the following structures, Ar₂ and Ar₃ are each independently selected from any one or more of a substituted or unsubstituted aryl group having 6 to 14 ring atoms, and a substituted or unsubstituted heteroaryl group having 5 to 14 ring atoms.

This application claims priority to and the benefit of Chinese Patent Application No. 202311745725.9, filed on Dec. 15, 2023, the disclosure of which is incorporated herein by reference in its entirety.

### TECHNICAL FIELD

The present disclosure relates to the field of organic materials, and in particular, to a polymer, a composition, and an optoelectronic device.

### BACKGROUND

The hole transport material refers to a material having performance of hole transport properties. At present, commonly used hole transport materials have low hole mobility and poor matching with commonly used metal oxide electron transport materials.

Therefore, it is urgent to develop new hole transport materials and expand the types of hole transport materials.

### SUMMARY

Therefore, the present disclosure provides a polymer, a composition, and an optoelectronic device.

In a first aspect, the present disclosure provides a polymer having a structure of formula (I):

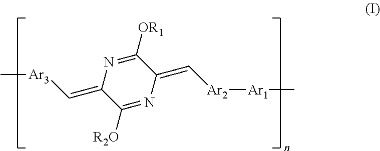

wherein:
n is any integer from 10 to 50;
Ar₁ is selected from any one of the following structures:

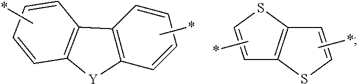

Ar₂ and Ar₃ are each independently selected from any one or more of a substituted or unsubstituted aryl group having 6 to 14 ring atoms, and a substituted or unsubstituted heteroaryl group having 5 to 14 ring atoms;
Y is selected from any one of CR₃R₄, S, NR₅ and O;
R₁, R₂, R₃, R₄, and R₅ are each independently selected from any one or more of H, D, and substituted or unsubstituted C₁-C₃₀ alkyl;
a substituent is selected from one or more of hydroxyl, amino, halogen, carboxyl, nitro, a sulfonic acid group, aldehyde, a thiol group, cyano, C₁-C₅ alkyl, C₁-C₅ alkoxy, and C₁-C₅ alkyl-substituted carbonyl;
* represents site of attachment.

In a second aspect, the present disclosure provides a composition including a solvent and a polymer having a structure of formula (I):

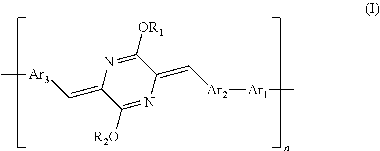

wherein:
n is any integer from 10 to 50;
Ar₁ is selected from any one of the following structures:

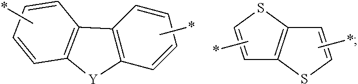

Ar₂ and Ar₃ are each independently selected from any one or more of a substituted or unsubstituted aryl group having 6 to 14 ring atoms, and a substituted or unsubstituted heteroaryl group having 5 to 14 ring atoms; Y is selected from any one of CR₃R₄, S, NR₅ and O; R₁, R₂, R₃, R₄, and R₅ are each independently selected from any one or more of H, D, and substituted or unsubstituted C₁-C₃₀ alkyl; a substituent is selected from one or more of hydroxyl, amino, halogen, carboxyl, nitro, a sulfonic acid group, aldehyde, a thiol group, cyano, C₁-C₅ alkyl, C₁-C₅ alkoxy, and C₁-C₅ alkyl-substituted carbonyl; * represents site of attachment.

In a third aspect, the present disclosure provides an optoelectronic device including an anode, a hole functional layer, and a cathode, wherein a material of the hole functional layer includes the polymer having a structure represented by formula (I):

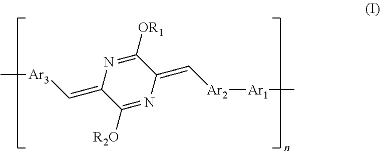

wherein:
n is any integer from 10 to 50;
Ar₁ is selected from any one of the following structures:

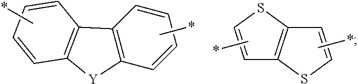

Ar₂ and Ar₃ are each independently selected from any one or more of a substituted or unsubstituted aryl group having 6 to 14 ring atoms, and a substituted or unsubstituted heteroaryl group having 5 to 14 ring atoms; Y is selected from any one of CR₃R₄, S, NR₅ and O; R₁, R₂, R₃, R₄, and R₅ are each independently selected from any one or more of H, D, and substituted or unsubstituted C₁-C₃₀ alkyl; a substituent is selected from one or more of hydroxyl, amino, halogen, carboxyl, nitro, a sulfonic acid group, aldehyde, a thiol group, cyano, C₁-C₅ alkyl, C₁-C₅ alkoxy, and C₁-C₅ alkyl-substituted carbonyl; * represents site of attachment.

### BRIEF DESCRIPTION OF THE DRAWINGS

In order to more clearly explain the technical solutions in the embodiments of the present disclosure, the figures to be used in the description of the embodiments are briefly described below. It is apparent that the figures in the following description are merely some embodiments of the present disclosure. For those skilled in the art, without involving any creative effort, other figures may be obtained based on these figures.

FIG. 1 is a schematic diagram of an optoelectronic device according to an embodiment of the present disclosure.

### DETAILED DESCRIPTION

Technical solutions in embodiments of the present disclosure will be clearly and completely described below with reference to the figures in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure. Furthermore, it should be understood that the detailed description described herein is for illustration and explanation of the present disclosure only, and is not intended to limit the present disclosure. In the present disclosure, unless otherwise stated, location words such as “upper” and “lower” are used to specifically refer to the plane direction in the drawings. Additionally, in the description of the present disclosure, the term “including” means “including but not limited to”. Various embodiments of the present disclosure may exist in a range of forms. It should be understood that the description in a range form is for convenience and brevity only, and should not be construed as a hard limitation on the scope of the present disclosure. Accordingly, it should be considered that the stated range description has specifically disclosed all possible sub-ranges as well as single numerical values within the range. For example, it should be considered that a range from 1 to 6 has specifically disclosed subranges, such as from 1 to 3, from 1 to 4, from 1 to 5, from 2 to 4, from 2 to 6, from 3 to 6, and the like, and single numbers within the range, such as 1, 2, 3, 4, 5, and 6, which apply regardless of the range. In addition, whenever a numerical range is indicated herein, it is meant to include any referenced number (fraction or integer) within the indicated range.

In the present disclosure, “and/or” describes the association relationship of the association object, and indicates that there may be three kinds of relationships, for example, A and/or B, which may indicate that A exists alone, A and B exist at the same time, and B exists alone. A and B may be singular or plural.

In the present disclosure, “at least one” refers to one or more, and “a plurality” refers to two or more. “at least one of the following”, or similar expressions thereof refer to any combination of these items, including any combination of single or plural items. For example, “at least one of a, b, or c”, or “at least one of a, b, and c” may all mean: a, b, c, a-b (that is, a and b), a-c, b-c, or a-b-c, wherein a, b, and c, may be a single item or a plurality of items, respectively.

In the present disclosure, an aryl, an aromatic group, and an aromatic ring have the same meaning and are interchangeable.

In the present disclosure, a heteroaryl group, a heteroaromatic group, and a heteroaromatic ring system have the same meaning and may be interchangeable.

In the present disclosure, “substituted or unsubstituted” means that the defined group may or may not be substituted. When a defined group is substituted and no definition is otherwise provided, “substituted” means that a hydrogen of a compound or group is replaced by one or more of a deuterium atom, halogen, hydroxyl, nitro, cyano, isocyano, amino, azide, amidino, hydrazino, hydrazone, carbonyl, carbamoyl, a thiol group, an ester group, carboxyl or a salt thereof, a sulfonic acid group or a salt thereof, a phosphoric acid group or a salt thereof, a silyl group, C₁-C₂₀ alkyl, C₂-C₂₀ alkenyl, C₂-C₂₀ alkynyl, C₆-C₃₀ aryl, C₇-C₃₀ aralkyl, C₁-C₃₀ alkoxy, C₁-C₂₀ heteroalkyl, C₃-C₂₀ heterocyclic group, C₃-C₂₀ heteroaralkyl, C₃-C₃₀ cycloalkyl, C₃-C₁₅ cycloalkenyl, C₆-C₁₅ cycloalkynyl, and C₃-C₃₀ heterocycloalkyl.

In the present disclosure, in a structural compound obtained by connecting atoms to form a ring (for example, a monocyclic compound or a fused ring compound), the number of ring atoms refers to the number of ring atoms constituting the ring itself, that is, the number of atoms forming a ring. When the ring is substituted with a substituent, the atoms contained in the substituent are not included in the ring atoms. The same applies to the “number of ring atoms” described below unless otherwise specified. For example, the number of ring atoms of the benzene ring is 6, the number of ring atoms of the naphthalene ring is 10, and the number of ring atoms of the thienyl group is 5.

In the present disclosure, the “aryl or aromatic group” refers to an aromatic hydrocarbon group derived by removing one hydrogen atom from an aromatic ring compound, and may be a monocyclic aryl group, a fused ring aryl group, or a polycyclic aryl group. At least one of the polycyclic rings is an aromatic ring. For example, “substituted or unsubstituted aryl having 6 to 40 ring atoms” refers to an aryl group containing 6 to 40 ring atoms, and the aryl group may optionally be further substituted. Preferably a substituted or unsubstituted aryl group having 6 to 30 ring atoms, more preferably a substituted or unsubstituted aryl group having 6 to 18 ring atoms, particularly preferably a substituted or unsubstituted aryl group having 6 to 14 ring atoms and optionally further substituted on the aryl group. Suitable examples include, but are not limited to, phenyl, biphenyl, terphenyl, naphthyl, anthryl, phenanthryl, fluoranthryl, triphenylene, pyrenyl, pyrylo, tetraphenyl, fluorenyl, perylene, acenaphthenyl, and derivatives thereof. It will be understood that a plurality of aryl groups may also be interrupted by short non-aromatic units (for example non-aromatic units having less than 10% non-hydrogen atoms which may be C, N or O atoms), such as acenaphthene, fluorene, or 9, 9-diarylfluorene, triarylamine, diaryl ether systems should also be included in the definition of aryl groups.

In the present disclosure, the “heteroaryl group or heteroaromatic group” means that at least one carbon atom of the aryl is replaced with a non-carbon atom, and the non-carbon atom may be an N atom, an O atom, an S atom, a Si atom, a P atom, or the like. For example, “substituted or unsubstituted heteroaryl group having 5 to 40 ring atoms” refers to a heteroaryl having 5 to 40 ring atoms, preferably substituted or unsubstituted heteroaryl having 6 to 30 ring atoms, more preferably substituted or unsubstituted heteroaryl having 6 to 18 ring atoms, particularly preferably substituted or unsubstituted heteroaryl having 6 to 14 ring atoms, and the heteroaryl is optionally further substituted. Suitable examples include, but are not limited to, thienyl, furanyl, pyrrolyl, oxadiazolyl, triazolyl, imidazolyl, pyridinyl, bipyridinyl, pyrimidinyl, triazinyl, acridinyl, pyridazinyl, pyrazinyl, quinolyl, isoquinolyl, quinazolinyl, quinoxalinyl, phthalazinyl, pyrido pyrimidine group, pyrido pyrazine group, benzothienyl, benzofuranyl, indolyl, pyrroloimidazole group, pyrrolopyrrolyl, thienopyrrolyl, thienothienyl, furopyrrolyl, furofuranyl, thienofuranyl, benzisoxazolyl, benzisothiazolyl, benzimidazolyl, ortho-naphthyl, phenanthridinyl, primary ridinyl, quinazolinone, dibenzothienyl, dibenzofuranyl, carbazolyl and derivatives thereof.

In the present disclosure, “alkyl” may mean one or more of unbranched chain alkyls, branched chain alkys, and cyclic alkyl groups. Alkyl may have a carbon number of 1 to 50, 1 to 30, 1 to 20, 1 to 10 or 1 to 6. Phrases containing this term, for example, “C₁-C₉ alkyl” refers to an alkyl group containing 1 to 9 carbon atoms, and each occurrence can be independently C₁ alkyl, C₂ alkyl, C₃ alkyl, C₄ alkyl, C₅ alkyl, C₆ alkyl, C₇ alkyl, C₈ alkyl or C₉ alkyl. Non-limiting examples of alkyl groups include methyl, ethyl, n-propyl, isopropyl, n-butyl, sec-butyl, tert-butyl, isobutyl, 2-ethylbutyl, 3, 3-dimethylbutyl, n-pentyl, isopentyl, neopentyl, tert-pentyl, cyclopentyl, 1-methylpentyl, 3-methylpentyl, 2-ethylpentyl, 4-Methyl-2-pentyl, n-hexyl, 1-methylhexyl, 2-ethylhexyl, 2-butylhexyl, cyclohexyl, 4-methylcyclohexyl, 4-tert-butylcyclohexyl, n-heptyl, 1-methylheptyl, 2, 2-dimethylheptyl, 2-ethylheptyl, 2-butylheptyl, n-octyl, tert-octyl, 2-ethyloctyl, 2-butyloctyl, 2-hexyloctyl, 3, 7-dimethyloctyl, cyclooctyl, n-nonyl, n-decyl, adamantyl, 2-ethyldecyl, 2-butyldecyl, 2-hexyldecyl, 2-octyldecyl base, n-undecyl, n-dodecyl, 2-ethyldodecane base, 2-butyldodecyl, 2-hexyldodecyl, 2-octyldodecyl, n-tridecyl, n-tetradecyl, n-pentadecyl, n-hexadecyl base, 2-ethyl hexadecyl, 2-butyl hexadecyl, 2-Hexyl hexadecyl, 2-octyl hexadecyl, n-heptadecyl, n-octadecyl, n-nonadecyl, n-eicosanyl, 2-ethyl eicosanyl, 2-Butyl eicosanyl, 2-hexyl eicosanyl, 2-octyl eicosanyl Alkyl, n-21 alkyl, n-22 alkyl, n-2 alkyl, n-2 alkyl, n-2 alkyl, n-2 alkyl, n-2 alkyl, n-2 alkyl, n-2 alkyl base, n-octadecyl, n-nonadecyl, n-triacontyl, and so on.

In the present disclosure, “—CₙH₂ₙ₊₁” means a unbranched chain alkyl unless otherwise specified or limited. For example, —C₆H₁₃ represents n-hexyl, and —C₁₂H₂₅ represents n-dodecyl.

In the present disclosure, “alkoxy” refers to a group having a structure of “—O-alkyl”, that is, an alkyl group as defined above is attached to another group via an oxygen atom. Suitable examples of phrases encompassing the term include, but are not limited to: methoxy (—O—CH₃ or —OMe), ethoxy (—O—CH₂CH₃ or —OEt), and tert-butoxy (—O—C(CH₃)₃ or —OtBu).

In the present disclosure, “alkyl-substituted carbonyl” is

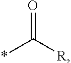

wherein R is an alkyl group as defined above.

In the present disclosure, “‘*’ linked to a single bond” denotes a site of attachment. When the site of attachment is not specified in the group, it means that an optional attachable site in the group serves as the site of attachment. For example, in

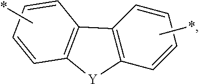

any attachable site on the two benzene rings can be used as the site of attachment.

“a combination thereof”, “any combination thereof”, “any combination thereof”, and the like as used in the present disclosure include all suitable combinations of any two or more of the listed items.

The present disclosure provides a polymer having a structure represented by Formula (I):

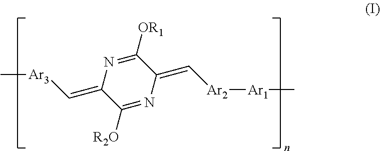

n is any integer from 10 to 50;
Ar₁ is selected from any one of the following structures:

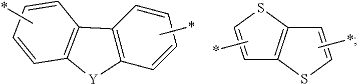

Ar₂ and Ar₃ are each independently selected from any one or more of a substituted or unsubstituted aryl group having 6 to 14 ring atoms, and a substituted or unsubstituted heteroaryl group having 5 to 14 ring atoms;
Y is selected from any one of CR₃R₄, S, NR₅ and O;
R₁, R₂, R₃, R₄, and R₅ are each independently selected from any one or more of H, D, and substituted or unsubstituted C₁-C₃₀ alkyl;
a substituent is selected from one or more of hydroxyl, amino, halogen, carboxyl, nitro, a sulfonic acid group, aldehyde, a thiol group, cyano, C₁-C₅ alkyl, C₁-C₅ alkoxy, and C₁-C₅ alkyl-substituted carbonyl;
* represents site of attachment.

In some embodiments, an average of polymerization degree of the polymer is n which is any integer from 10 to 50. For example, n may be 10, 15, 20, 25, 30, 35, 40, 45, 50, or a value between any two of the above values. By controlling the polymerization degree within this range, it helps to improve the stability and hole transport characteristics of the polymer, reduce defects, and ensure its solubility and solution processability.

In some embodiments, the polymer has a number-average molecular weight of 20,000 to 80,000. For example, the number-average molecular weight of the polymer may be 20,000, 25,000, 26,200, 30,000, 31,000, 31,900, 32,000, 40,000, 45,000, 48,000, 50,000, 55,000, 60,000, 64,000, 65,000, 70,000, 80,000, or a value between any two of the above values.

In some embodiments, R₁ and R₂ are each independently selected from C₆-C₂₄ alkyl. And in some embodiments, R₁ and R₂ are the same.

In some embodiments, R₃ and R₄ are each independently selected from C₁-C₈ alkyl. And in some embodiments, R₃ and R₄ are the same.

In some embodiments, R₅ is selected from any one or more of H, D, and C₁-C₁₆ alkyl.

In some embodiments, Y is selected from CR₃R₄.

In some embodiments, Ar₂ and Arₙ are each independently selected from any one of the following structures:

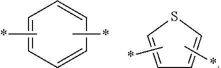

In other embodiments, Ar₂ and Ar₃ are each independently selected from any one of the following structures:

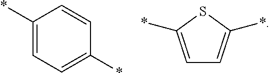

In some embodiments, Ar₂ and Ar₃ are the same.

In some embodiments, the polymer has one of the structures shown below:

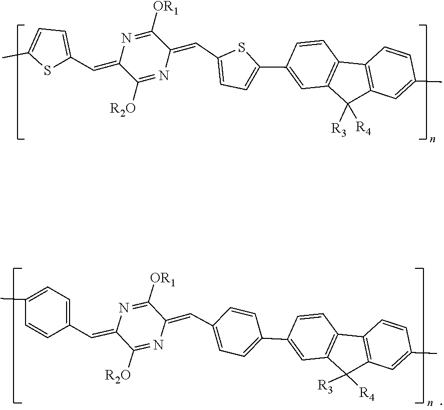

In some specific embodiments, the polymer includes one or more of the following structural formulae:

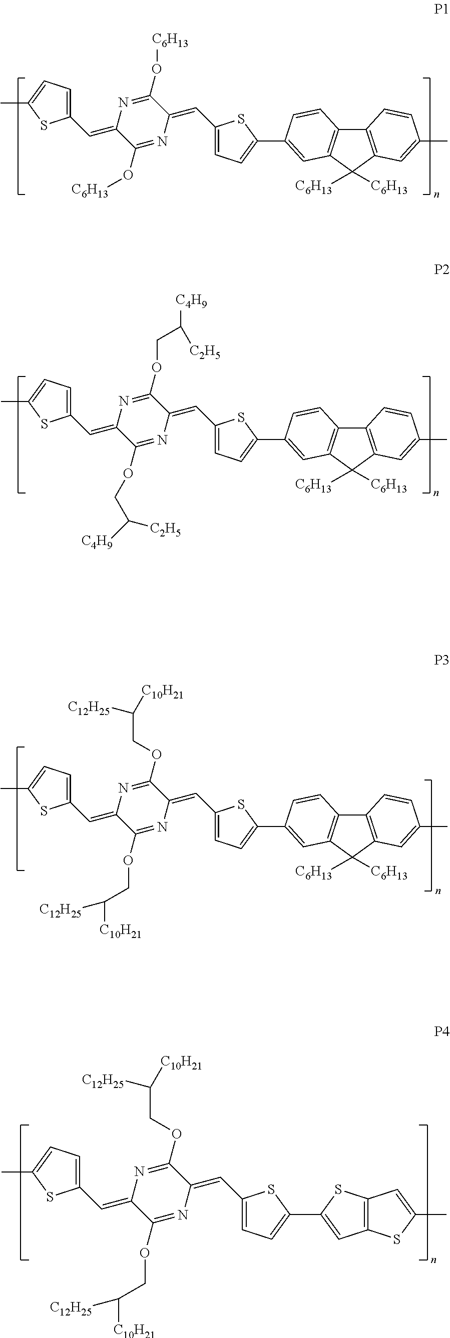

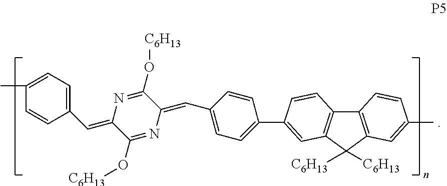

In the structure of the polymer proposed in the embodiment of the present disclosure, Ar₁ is a fused group and has a rigid plane, and a larger conjugated system makes the polymer have greater rigidity, which is conducive to intermolecular stacking, and further conducive to hole transport. A nitrogen doped p-benzoquinone unit has a quinoid structure, which can enhance the resonance effect, further expand the electron cloud distribution on the main chain, enhance the degree of electron delocalization, and effectively enhance the intermolecular p-orbital overlap and π-π interaction. Moreover, the quinoid structure further enhances the planar rigid structure of the molecule, thereby greatly improving the transmission characteristics, effectively reducing the HOMO energy level of the molecule, and making the energy level matching between the polymer and commonly used light-emitting materials better. When the polymer is used to prepare a hole-functional layer 50, the potential barrier between the hole-functional layer 50 and a light-emitting layer 40 is reduced, and hole injection is enhanced.

In some embodiments, such polymers may be used to prepare the hole functional layer 50 of the optoelectronic device 100. The good hole transport performance of the polymer makes it possible to enhance the hole injection ability, improve the carrier balance of the device, and enhance the photoelectric performance and service life of the device when it is used to fabricate the hole functional layer 50. In addition, the polymer has a lower HOMO energy level and is well matched with the light-emitting layer 40. When the polymer is used to prepare the hole-functional layer 50, it helps to reduce the potential barrier between the hole-functional layer 50 and the light-emitting layer 40, enhance hole injection, and further enhance the photoelectric performance and service life of the device.

In some embodiments, a hole mobility of the polymer ranges from 10⁻³ to 10⁻² cm² V⁻¹ s⁻¹. For example, the hole mobility of the polymer may be 1.0×10⁻³ cm² V⁻¹ s⁻¹, 1.5×10⁻³ cm² V⁻¹ s⁻¹, 2×10⁻³ cm² V⁻¹ s⁻¹, 2.5×10⁻³ cm² V⁻¹ s⁻¹, 3×10⁻³ cm² V⁻¹ s⁻¹, 4×10⁻³ cm² V⁻¹ s⁻¹, 4.5×10⁻³ cm² V⁻¹ s⁻¹, 5×10⁻³ cm² V⁻¹ s⁻¹, 6×10⁻³ cm² V s⁻¹, 7×10⁻³ cm² V⁻¹s⁻¹, 8×10⁻³ cm² V⁻¹ s⁻¹, 9×10⁻³ cm² V⁻¹ s, 1.0×10⁻² cm² V⁻¹ s⁻¹, or a value between any two of the above values. The polymer has a high hole mobility.

In some embodiments, a HOMO level of the polymer ranges from −5.0 eV to −5.4 eV. For example, the HOMO level of the polymer may be −5.0 eV, −5.1 eV, −5.2 eV, −5.3 eV, −5.4 eV, or a value between any two of the above values. The polymer has a lower HOMO level and is well matched to the light-emitting layer 40.

The present disclosure further provides a method of preparing a polymer, including the following steps.

In step S10, 1, 4-diacetylpiperazine-2, 5-dione and a compound M1 are mixed to perform a first reaction to obtain a compound M2.

In step S20, the compound M2 with a compound M5 are mixed to perform a second reaction to obtain a compound M3.

In step S30, the compound M3 and a compound M4 are mixed to perform a third reaction to obtain a polymer P.

Wherein the compound M1, the compound M2, the compound M3, and the polymer P each have the following structural formula:

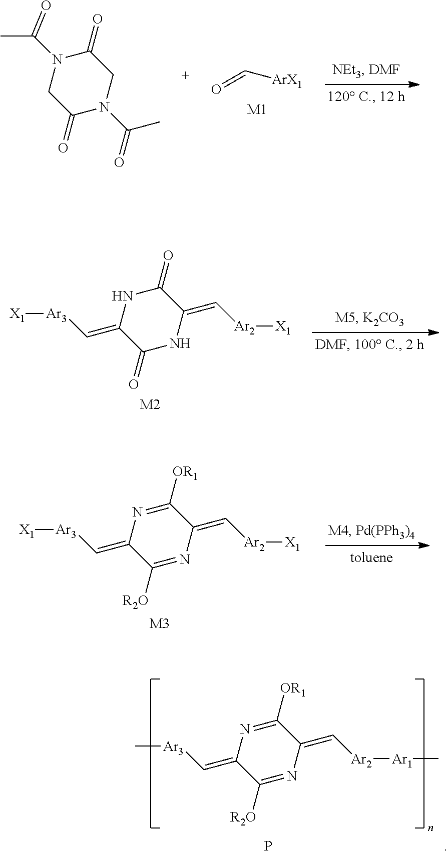

Wherein Ar represents Ar₂ or Ar₃, the compound M5 includes a mixture of a compound having a general formula R₁X₂, and a compound having a general formula R₂X₂, and the compound M4 is selected from one of the following structures:

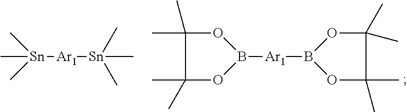

X₁ and X₂ are each independently selected from —Cl, —Br or —I; R₁ and R₂ are each independently selected from one or more of H, D, and substituted or unsubstituted C₁-C₃₀ alkyl.

Ar₁ is selected from any one of the following structures:

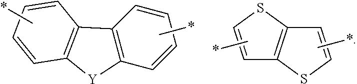

Ar₂ and Ar₃ are each independently selected from any one or more of a substituted or unsubstituted aryl group having 6 to 14 ring atoms, and a substituted or unsubstituted heteroaryl group having 5 to 14 ring atoms.

Y is selected from any one of CR₃R₄, S, NR₅ and O; R₃, R₄, and R₅ are each independently selected from any one or more of H, D, and substituted or unsubstituted C₁-C₃₀ alkyl; a substituent is selected from one or more of hydroxyl, amino, halogen, carboxyl, nitro, a sulfonic acid group, aldehyde, a thiol group, cyano, C₁-C₅ alkyl, C₁-C₅ alkoxy, and C₁-C₅ alkyl-substituted carbonyl; n is any integer from 10 to 50.

* represents site of attachment.

In some embodiments, a molar ratio of the 1, 4-diacetylpiperazine-2, 5-dione and the compound M1 is 1:(2-3); for example, it may be 1:2, 1:2.2, 1:2.5, 1:2.7, 1:2.9, 1:3, or a value between any two of the above values.

In some embodiments, a reaction temperature of the first reaction ranges from 100° C. to 150° C.; for example, the reaction temperature may be 100° C., 105° C., 110° C., 120° C., 130° C., 140° C., 150° C., or a value between any two of the above values.

In some embodiments, a reaction time of the first reaction ranges from 10 h to 24 h; for example, it may be 10 h, 12 h, 15 h, 18 h, 20 h, 22 h, 24 h, or a value between any two of the above values.

In some embodiments, a molar ratio of the compound M2 to the compound M5 is 1:(2-5); for example, it may be 1:2, 1:3, 1:4, 1:5, or a value between any two of the above values.

In some embodiments, a reaction temperature of the second reaction ranges from 80° C. to 120° C.; for example, it may be 80° C., 85° C., 90° C., 95° C., 100° C., 105° C., 110° C., 120° C., or a value between any two of the above values.

In some embodiments, a reaction time of the second reaction ranges from 1 h to 3 h; for example, it may be 1 h, 1.5 h, 2 h, 2.5 h, 3 h, or a value between any two of the above values.

In some embodiments, a molar ratio of the compound M3 to the compound M4 is 1:(0.8-1.5); for example, it may be 1:0.8, 1:1, 1:1.2, 1:1.4, 1:1.5, or a value between any two of the above values.

In some embodiments, a reaction temperature of the third reaction ranges from 100° C. to 150° C.; for example, it may be 100° C., 105° C., 110° C., 120° C., 130° C., 140° C., 150° C., or a value between any two of the above values.

In some embodiments, a reaction time of the third reaction ranges from 4 h to 24 h, for example, it may be 4 h, 6 h, 8 h, 12 h, 15 h, 18 h, 20 h, 22 h, 24 h, or a value between any two of the above values.

In some embodiments, when the compound M4 is selected from

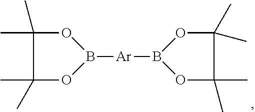

step S30 may be carried out as follows: under inert gas protection, the compound M3 and the compound M4 are mixed, a palladium catalyst, methyl trioctyl ammonium chloride and a solvent are added, a temperature is raised to 90-110° C., an aqueous solution of sodium carbonate is added, and then the temperature is raised to 115-130° C. for the third reaction to obtain the polymer P.

In some embodiments, when the compound M4 is selected from

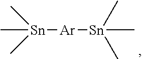

step S30 may be carried out as follows: under inert gas protection, the compound M3 and the compound M4 are mixed, the palladium catalyst and the solvent are added, the temperature is raised to 100° C.-150° C. to reflux the reaction solution, a reaction is carried out for 4 to 24 hours, and the reaction is monitored. When a solution having the polymer turns dark purple and a concentration of the solution increases significantly, the reaction is stopped to obtain the polymer P.

In the above step, the palladium catalyst used may be a palladium catalyst commonly used in the field, such as tris(dibenzylideneacetone)dipalladium (Pd₂(dba)₃), tetrakis(triphenylphosphine)palladium (pd(pph₃)₄) and the like. In some embodiments, a molar ratio of the compound M3 to the palladium catalyst is 1:(0.1-0.2). For example, it may be 1:0.1, 1:0.12, 1:0.15, 1:0.17, 1:0.18, 1:0.19, 1:0.2, or a value between any two of the above values.

In some embodiments, a molar ratio of the compound M3 to the sodium carbonate is 1:8 to 1:15, for example, it may be 1:8, 1:9, 1:10, 1:11, 1:12, 1:13, 1:14, 1:15, or a value between any two of the above values.

Embodiments of the present disclosure also provide a composition including a solvent and a polymer. The polymer includes a polymer as described above, or includes a polymer prepared as described above. Using the composition, a thin film having a hole transport property may be prepared, which may be used as the hole functional layer 50 of the optoelectronic device 100.

In some embodiments, a concentration of the polymer in the composition may range from 5 mg/ml to 30 mg/ml. For example, it may be 5 mg/ml, 6 mg/ml, 7 mg/ml, 8 mg/ml, 9 mg/ml, 10 mg/ml, 12 mg/ml, 15 mg/ml, 18 mg/ml, 20 mg/ml, 22 mg/ml, 25 mg/ml, 30 mg/ml, or a value between any two of the above values.

In some embodiments, the solvent includes one or more of chlorobenzene, toluene, xylene, 1,2-dichlorobenzene.

In some embodiments, the preparation of a thin film using the above composition may be carried out by coating the composition on a substrate, removing the solvent to cure to form a film, and then annealing at 100-250° C. for 10-30 minutes to obtain the thin film. Among them, the substrate may be a glass substrate, a PI substrate, a semi-finished device made in a previous step in the manufacturing process of the optoelectronic device 100, or the like.

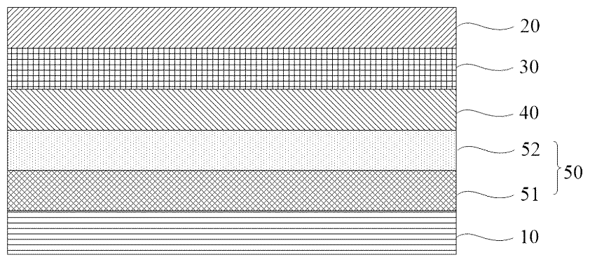

Further, embodiments of the present disclosure also provide an optoelectronic device 100, as shown in FIG. 1, the optoelectronic device 100 includes an anode 10, a hole functional layer 50, and a cathode 20, and the material of the hole functional layer 50 includes the polymer as described above, or includes a polymer prepared by the method as described above, or is made of the composition as described above.

The material of the hole functional layer 50 includes the polymer as described above, and the polymer has a unique frontier orbital hybridization mode and high hole mobility. When the hole functional layer 50 is prepared, the hole injection ability may be well enhanced, the carrier balance of the device may be improved, and the photoelectric performance and service life of the device may be enhanced. In addition, the polymer has a narrow band gap width, a lower HOMO energy level, and is well matched with the light-emitting layer 40. When the polymer is used to prepare the hole functional layer 50, it helps to reduce the potential barrier between the hole functional layer 50 and the light-emitting layer 40, enhance hole injection, and further enhance the photoelectric performance and service life of the device.

In some embodiments, the hole functional layer 50 includes one or both of a hole transport layer 52 and a hole injection layer 51, and when the hole functional layer 50 includes the hole transport layer 52 and the hole injection layer 51, the hole injection layer 51 is located between the hole transport layer 52 and the anode 10.

In some embodiments, the material of the hole transport layer 52 includes the polymer as described above or is made of the composition as described above. In other embodiments, the material of the hole transport layer 52 also includes other common hole transport materials. For example, the common hole transport materials may include, but not limited to, 4,4′-N,N′-dicarbazole-biphenyl (CBP), poly[(9,9-dioctylfluorenyl-2,7-diyl)-co-(4,4′-(N-(4-sec-butylphenyl) diphenylamine)](TFB), N,N′-Bis(naphthalen-1-yl)-N,N′-bis(phenyl)benzidine (α-NPD), N,N′-Bis(3-methylphenyl)-N,N′-bis(phenyl)benzidine (TPD), N,N′-Bis(3-methylphenyl)-N,N′-diphenyl-9,9-spirobifluorene-2,7-diamine (Spiro-TPD), N1,N1′-(Biphenyl-4,4′-diyl)bis(N1-phenyl-N4,N4-di-m-tolylbenzene-1,4-diamine) (DNTPD), 4,4′,4″-Tris(N-3-methylphenyl-N-phenylamino)triphenylamine (m-MTDATA), poly(p-phenyl vinyl) (PPV), poly[2-methoxy-5-(2-ethylhexyloxy)-1,4-phenylenevinylene](MEH-PPV), poly[2-methoxy-5-(3′,7′-dimethyloctyloxy)-1,4-phenylenevinylene](MOMO-PPV), 4,4′-Bis(N-carbazolyl)-1,1′-biphenyl, N,N,N′,N′-Tetraphenylbenzidine, PEDOT:PSS and its derivatives, poly(N-vinyl carbazole) (PVK) and its derivatives, poly(9,9-dioctylfluorene) and its derivatives, and spiro-NPB.

The material of the hole injection layer 51 may be a material having hole injection properties known in the field and commonly used for the hole injection layer 51 of the optoelectronic device 100, and may include, for example, but not limited to, at least one of dipyrazino[2,3-f:2′,3′-h]quinoxaline-2,3,6,7,10,11-hexacarbonitrile, PEDOT, PEDOT:PSS, a derivative doped with s-MoO₃, 4,4′,4″-Tris(N-3-methylphenyl-N-phenylamino)triphenylamine, 7,7,8,8-tetracyanoquinodimethane, copper phthalocyanine, nickel oxide, molybdenum oxide, tungsten oxide, vanadium oxide, molybdenum sulfide, tungsten sulfide, and copper oxide.

In some embodiments, the anode 10 and the cathode 20 are each independently selected from the group consisting of a metal electrode, a carbon electrode, a doped or undoped metal oxide electrode, and a composite electrode. Wherein a material of the metal electrode is selected from at least one of Al, Ag, Cu, Mo, Au, Ba, Ca, Ni, Ir, and Mg; a material of the carbon electrode is selected from at least one of graphite, carbon nanotubes, graphene, and carbon fibers; a material of the doped or undoped metal oxide electrode is selected from at least one of ITO, FTO, ATO, AZO, GZO, IZO, MZO, ITZO, ICO, AMO, SnO₂, In₂O₃, Cd:ZnO, and Ga:SnO₂; a material of the composite electrode is selected from one of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS and ZnS/Al/ZnS.

In some embodiments, the optoelectronic device 100 further includes a light-emitting layer 40 disposed between the cathode 20 and the hole functional layer 50, and the material of the light-emitting layer 40 is selected from organic light-emitting materials or quantum dot light-emitting materials; the organic light-emitting materials are selected from at least one of the group consisting of a diarylanthracene derivative, a stilbene aromatic derivative, a pyrene derivative, a fluorene derivative, a blue-emitting TBPe fluorescent material, a green-emitting TTPA fluorescent material, an orange-emitting TBRb fluorescent material, and a red-emitting DBP fluorescent material; the quantum dot light-emitting materials are selected from at least one of the group consisting of a single structure quantum dot, a core-shell structure quantum dot, and a perovskite type semiconductor material; the single structure quantum dot is selected from at least one of a Group II-VI compound, a Group IV-VI compound, a Group III-V compound, and a Group I-III-VI compound, the Group II-VI compound is selected from at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the Group IV-VI compound is selected from at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe; the Group III-V compound is selected from at least one of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb; the Group I-III-VI compound is selected from one or more of CuInS₂, CuInSe₂, and AgInS₂. A core of the core-shell structure quantum dot is selected from any one of the single structure quantum dots as described above, and a shell material of the core-shell structure quantum dot is selected from at least one of CdS, CdTe, CdSeTe, CdZnSe, CdZnS, CdSeS, ZnSe, ZnSeS and ZnS.

As an example, the core-shell structure quantum dot may be selected from but not limited to at least one of CdZnSe/CdZnSe/ZnSe/CdZnS/ZnS, CdZnSe/CdZnSe/CdZnS/ZnS, CdSe/CdSeS/CdS, InP/ZnSeS/ZnS, CdZnSe/ZnSe/ZnS, CdSeS/ZnSeS/ZnS, CdSe/ZnS, CdSe/ZnSe/ZnS, ZnSe/ZnS, ZnSeTe/ZnS, CdSe/CdZnSeS/ZnS, and InP/ZnSe/ZnS.

For a material of the single structure quantum dot, a core material of the core-shell structure quantum dot, or the shell material of the core-shell structure quantum dot, the chemical formula provided only indicates the elemental composition and does not indicate the content of each element. For example, CdZnSe only indicates that a material is composed of three elements: Cd, Zn and Se. If it indicates the content of each element, it corresponds to CdₓZn₁₋ₓSe, 0<x<1.

The perovskite type semiconductor is selected from one of a doped inorganic perovskite type semiconductor, an undoped inorganic perovskite type semiconductor, and an organic-inorganic hybrid perovskite type semiconducto. A general structure formula of the inorganic perovskite type semiconductor is AMX₃, wherein A is Cs+, M is a divalent metal cation selected from one of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, X is a halogen anion selected from one of Cl⁻, Br⁻, and I⁻; a general structure formula of the organic-inorganic hybrid perovskite type semiconductor is BMX₃, wherein B is an organic amine cation selected from CH₃(CH₂)ₙ₋₂NH₃⁺ (n≥2) or NH₃(CH₂)ₙNH₃²⁺ (n≥2), M is a divalent metal cation selected from one of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, X is a halogen anion selected from one of Cl⁻, Br⁻, and I⁻.

In some embodiments, the optoelectronic device 100 further includes an electron transport layer 30 disposed between the light-emitting layer 40 and the cathode 20, and a material of the electron transport layer 30 includes one or more of a metal oxide, a doped metal oxide, a group IIB-VIA material, a group IIIB-VA material, and a group IB-IIIB-VIA material. The metal oxide includes one or more of ZnO, TiO₂, and SnO₂. A metal oxide in the doped metal oxide includes one or more of ZnO, TiO₂, and SnO₂, and a doping element in the doped metal oxide includes one or more of Al, Mg, Li, In, and Ga. The group IIB-VIA material includes one or more of ZnS, ZnSe, CdS, and CdSe. The Group IIIB-VA material includes one or more of InP and GaP. The group IB-IIIB-VIA material includes one or more of CuInS and CuGaS.

It may be understood that the optoelectronic device 100 may also add some functional layers conventionally used for the optoelectronic device 100 to help improve the performance of the optoelectronic device 100, such as an electron blocking layer, a hole blocking layer, an interface modification layer, and the like.

It may be understood that materials of each layer of the optoelectronic device 100 may be adjusted according to the actual needs of the optoelectronic device 100.

It may be understood that the optoelectronic device 100 may further include an encapsulation layer (not shown in FIG. 1) to insulate water oxygen (for example, to make a concentration of oxygen and water below 0.1 ppm) and improve the performance stability of the optoelectronic device 100. Specifically, an encapsulation material used for forming the encapsulation layer may be selected from at least one of UV glue, metal film, and glass glue. In a specific embodiment, the encapsulation material may be acrylic resin or epoxy resin.

The present disclosure also provides a method for preparing an optoelectronic device 100, which may prepare the optoelectronic device 100 as described above. The method includes the following steps.

In step S1, a first electrode is provided.

In step S2, at least one functional layer including a hole functional layer 50 is provided on the first electrode.

In step S3, a second electrode is provided on the at least one functional layer.

In steps S1 and S3, the first electrode is selected from one of the anode 10 and the cathode 20, and the second electrode is selected from the other of the anode 10 and the cathode 20. In actual preparation, it is determined whether the anode 10 or the cathode 20 is prepared first according to the film design of the optoelectronic device 100. For example, when the optoelectronic device 100 is designed such that the anode 10 is on the lowermost layer and the cathode 20 is on the uppermost layer, the anode 10 is prepared first, and the first electrode is the anode 10.

However, the preparation of the hole functional layer 50 may be made with reference to the above-described method for preparing a thin film using the composition, and will not be described in detail here.

It may be understood that the preparation of at least one functional layer may be sequentially prepared in accordance with the film layer design order of the optoelectronic device 100.

In actual preparation, the at least one functional layer, as well as the anode 10 and the cathode 20, may be prepared using techniques conventional in the field, such as chemical methods or physical methods. Among them, the chemical methods include chemical vapor deposition method, continuous ion layer adsorption and reaction method, anodic oxidation method, electrolytic deposition method and co-precipitation method. The physical methods include a physical coating method and a solution method, wherein the physical coating method includes: a thermal evaporation coating method, an electron beam evaporation coating method, a magnetron sputtering method, a multi-arc ion coating method, a physical vapor deposition method, an atomic layer deposition method, a pulsed laser deposition method, and the like; the solution method may be a spin coating method, a printing method, an ink jet printing method, a blade coating method, a printing method, a dipping and pulling method, a soaking method, a spray coating method, a roll coating method, a casting method, a slit coating method, a strip coating method, or the like.

In some embodiments, the step of packaging the optoelectronic device 100 is further included after the step S3. The packaging process may be performed by a conventional machine packaging or by a manual packaging. Preferably, in the environment of the packaging process, the oxygen content and the water content are both lower than 0.1 ppm to ensure the stability of the optoelectronic device 100.

The present disclosure also relates to a display device including an optoelectronic device 100 provided by the present disclosure. The display device may be any electronic product having a display function, and the electronic product includes, but is not limited to, a smartphone, a tablet computer, a notebook computer, a digital camera, a digital video camera, a smart wearable device, a smart weighing electronic scale, a vehicle-mounted display, a television, or an electronic book reader. The smart wearable device may be, for example, a smart bracelet, a smart watch, a Virtual Reality (VR) helmet, or the like.

Hereinafter, the present disclosure will be specifically described with reference to specific examples, and the following examples are only partial examples of the present disclosure and do not limit the present disclosure. The raw materials used in the following examples are commercially available products unless otherwise specified.

### Example 1

The structural formula of a polymer P1 of this example was as follows:

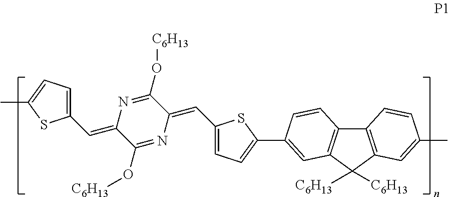

The synthetic route of the polymer P1 was as follows:

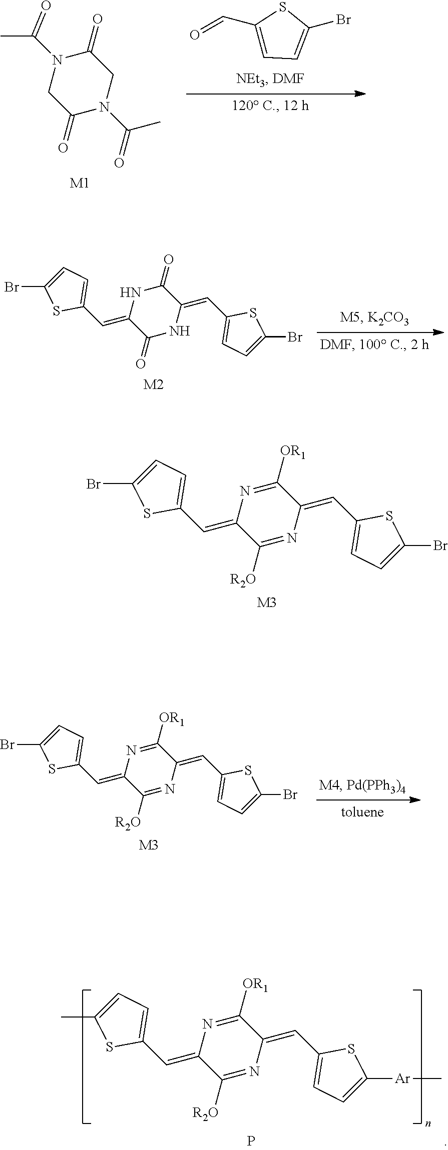

Wherein: M5 was RBr, R═—C₆H₁₃, and in M3, R1=R2=R.

M4 was

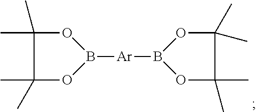

### Ar₁ was

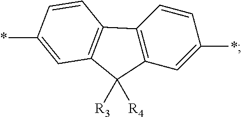

R₃═R₄═—C₆H₁₃.

Preparation of a compound M2: a compound M1 (1,4-diacetylpiperazine-2,5-dione, CAS: 3027-05-2; 2 g, 10 mmol, 1 eq.) and 5-bromo-2-thiophenecarbaldehyde (CAS: 4701-17-1; 4.82 g, 25 mmol, 2.5 eq.) were dispersed in DMF (46 ml) under the protection of N₂ atmosphere to make a mixed solution. To the mixed solution, triethylamine (CAS: 121-44-8; 4.82 g, 25 mmol, 2.5 eq.) was added dropwise through a syringe at 120° C. The colorless of the mixed solution turned red and a yellow precipitate was formed after reaction for 12 h. After cooling to room temperature, the precipitate was collected by filtration and rinsed with acetone to give a compound M2. The production output of the compound M2 was 2.8 g, and the yield of the compound M2 was 60%.

Preparation of a compound M3: the compound M2 (1.5 g, 3.2 mmol, 1 eq.), K₂CO₃ (2.25 g, 16 mmol, 5 1 eq.) and a compound M5 (1-bromo-n-hexane, CAS: 111-25-1; 2.2 g, 13 mmol, 4 1 eq.) were dispersed in 15 ml of DMF and stirred at 100° C. for 2 h. After cooling to room temperature, the mixture obtained by the reaction was filtered, and the filtrate was distilled under reduced pressure to obtain a solid substance. The solid substance was purified by column chromatography to obtain an orange solid which was the compound M3. The production output of the compound M3 was 2.63 g, and the yield of the compound M3 was 65%. The NMR data of the compound M3 was: ¹H NMR (CDCl₃): 7.05 (d, 2H), 6.91 (s, 2H), 6.88 (d, 2H), 3.58 (m, 4H), 1.30-1.50 (m, 16H), 0.88 (m, 6H).

Synthesis of a polymer P1: the compound M3 (628 mg, 1 mmol, 1 eq), the compound M4 (2,7-Bis(4,4,5,5-tetramethyl-1,3,2-dioxaborolan-2-yl)-9,9-dihexylfluorene, CAS: 254755-24-3; 586 mg, 1 mmol, 1 eq), Pd (PPh₃)₄(6.7 mg, 0.1 mmol, 0.1 eq) and 5 drops of Aliquat 336 phase transfer catalyst were added to a reaction flask. Subsequently, gas was exchanged three times with N₂, and 6 ml of anhydrous toluene was added to the reaction flask, and the temperature was raised to 100° C. to obtain a reaction solution. 5 ml of an aqueous solution of Na₂CO₃ having a concentration of 2 mol/L was slowly added dropwise to the reaction solution using a syringe to obtain a mixture, and the mixture was heated at 120° C. for 4 hours. After the reaction was stopped, the mixture was cooled to room temperature, the mixture was dropwise dropped into a stirred methanol solution to precipitate, and the polymer solids were collected by filtration. Then, the polymer solids were then extracted with a Soxhlet extractor. During the extraction, the solvents used were acetone and n-hexane in turn, and the extraction time was 24 h respectively, so as to remove impurities and low molecular weight oligomers in the polymer. Finally, the polymer was extracted with chlorobenzene to obtain a polymer solution. The polymer solution was concentrated by a rotary evaporator to obtain a concentrated polymer-chloroform solution, the concentrated polymer-chloroform solution was dropwise added to a methanol solution, and the concentrated polymer-chloroform solution was precipitated again, and then filtered to obtain polymer solids. The polymer solids were placed in a vacuum oven and dried at a temperature of 40° C. for 24 h to obtain a polymer P1. The structural formula of the polymer P1 was shown above, and n=31, the number-average molecular weight Mn=26.2 kDa, the production output of the polymer P1 was 581 mg, and the yield of the polymer P1 was 70%.

### Example 2

The structural formula of a polymer P2 was as follows:

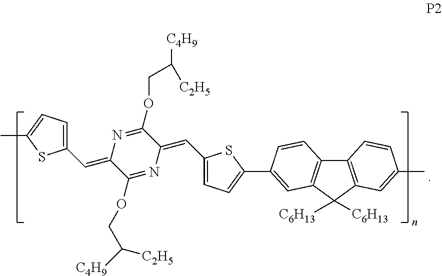

The synthesis procedure of the polymer P2 was similar to that of the polymer P1 except that the compound M5 was replaced with 2-ethylhexyl bromide (CAS: 18908-66-2) in the step of preparing the compound M3 in Example 1. That is, R, R₁, and R₂ in the compound M3 and the compound M5 were replaced by the following groups:

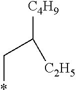

None of the other reaction conditions and amounts of substances were changed. The NMR data of the compound M3 prepared in this example was as follows: ¹H NMR (CDCl₃): 7.05 (d, 2H), 6.91 (s, 2H), 6.88 (d, 2H), 3.69 (m, 4H), 1.20-1.60 (m, 18H), 0.88 (m, 12H).

The structural formula of the polymer P2 was shown above, and n=36, the number-average molecular weight Mn=31.9 kDa, the production output of the polymer P2 was 620 mg.

### Example 3

The structural formula of a polymer P3 was as follows:

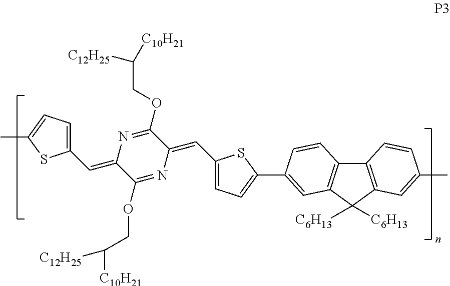

The synthesis procedure of the polymer P3 was similar to that of the polymer P1 except that the compound M5 was replaced with 11-(bromomethyl)tricosane (CAS: 732276-63-0) in the step of preparing the compound M3 in Example 1. That is, R, R₁, and R₂ in the compound M3 and the compound M5 were replaced by the following groups:

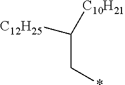

None of the other reaction conditions and amounts of substances were changed. The NMR data of the compound M3 prepared in this example was as follows: ¹H NMR (CDCl₃): 7.05 (d, 2H), 6.91 (s, 2H), 6.88 (d, 2H), 3.69 (m, 4H), 1.15-1.30 (m, 82H), 0.88 (m, 12H).

The structural formula of the polymer P3 was shown above, and n=48, the number-average molecular weight Mn=64.1 kDa, the production output of the polymer P3 was 935 mg.

### Example 4

The structural formula of a polymer P4 was as follows:

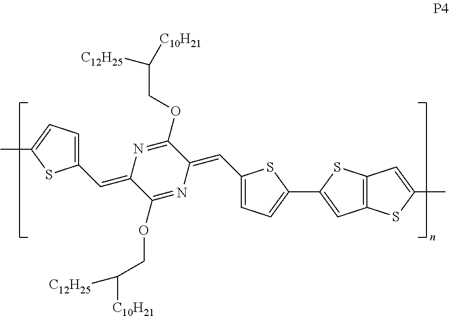

The synthesis procedure of the polymer P4 was similar to that of the polymer P3, except that in the preparation of the polymer P3 of Example 3, the following adjustments are made: the compound M4 was changed to 2,5-bis(triMethylstannyl)th ieno[3,2-b]thiophene (CAS: 469912-82-1), the catalyst was changed to Pd (PPh₃) 4 (6.7 mg, 0.1 mmol, 0.1 eq), the solvent was changed to toluene, the phase transfer catalyst was not added, and the reaction was carried out for 24 hours.

None of the other reaction conditions and amounts of substances were changed. The structural formula of the polymer P4 was shown above, and n=43, the number-average molecular weight Mn=48.4 kDa, the production output of the polymer P4 was 788 mg.

### Example 5

The structural formula of a polymer P5 was as follows:

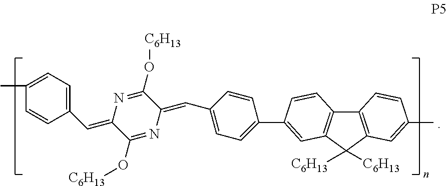

The synthetic route of the polymer P1 was as follows:

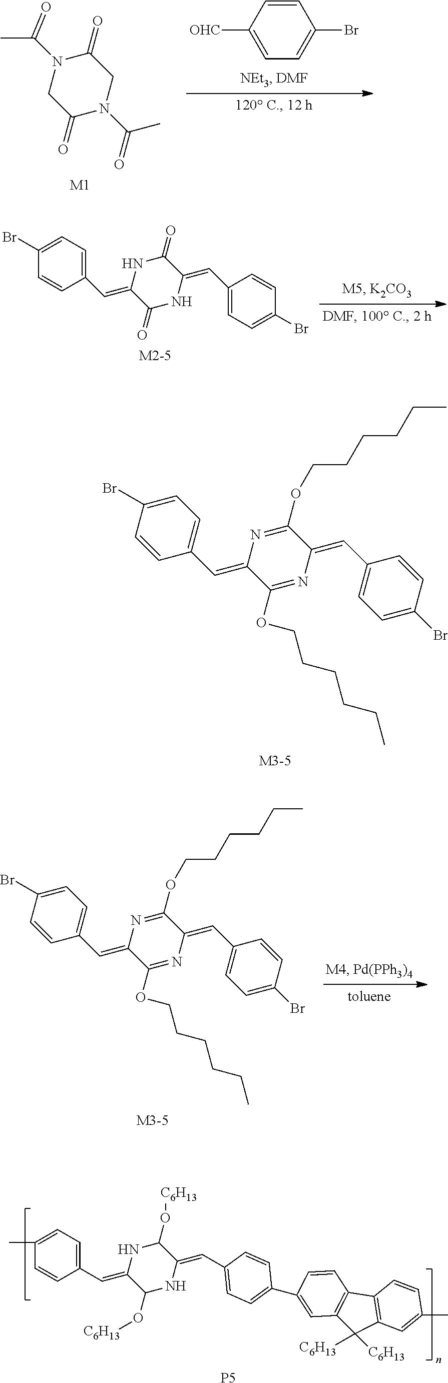

The synthesis procedure of the polymer P5 was similar to that of the polymer P1, except that in the preparation of the polymer P1 of Example 1, the following adjustments are made: the compound 5-bromo-2-thiophenecarbaldehyde was changed to 4-bromobenzaldehyde (CAS:1122-91-4). None of the other reaction conditions and amounts of substances were changed. The NMR data of the compound M3-5 prepared in this example was as follows: ¹H NMR (CDCl₃): 7.77 (d, 4H), 7.61 (d, 4H), 6.91 (s, 2H), 3.58 (d, 4H), 1.30-1.40 (m, 16H), 0.88 (m, 6H).

The structural formula of the polymer P5 was shown above, and n=24, the number-average molecular weight Mn=27.5 kDa, the production output of the polymer P5 was 614 mg, the yield of the polymer P5 was 75%.

### Comparative Example 1

The structural formula of polymer D1 is as follows:

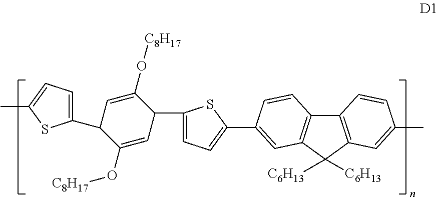

The synthesis procedure of the polymer D1 was similar to that of the polymer P1 except that the compound M3 was replaced with the following structural compound (CAS: 732276-63-0) in the step of preparing the polymer P1 in Example 1.

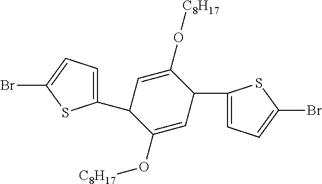

None of the other reaction conditions and amounts of substances were changed. The structural formula of the polymer D1 was shown above, and n=35, Mn=28.1 kDa, the production output of the polymer D1 was 562 mg.

### Comparative Example 2

This comparative example was TFB.

### Comparative Example 3

This comparative example was PVK.

### Device Example 1

A embodiment of the device provides a quantum dot light-emitting diode and a preparation method thereof, specifically including the following steps.

In step 1, take an ITO substrate as an anode. After the anode was cleaned and dried, the anode was treated in an ultraviolet ozone cleaner for 15 minutes for later use.

In step 2, PEDOT:PSS was spin-coated on the anode at 5000 rpm for 30 s, and then heated at 230° C. for 15 min to obtain a hole injection layer with a thickness of 100 nm.

In step 3, the polymer P1 prepared in Example 1 was dispersed in chlorobenzene to obtain a polymer solution with a concentration of 10 mg/ml. The polymer solution was spin-coated on the hole injection layer at a rotating speed of 2500 rpm and a spin-coating time of 30 s, and then heated at 200° C. for 30 min to obtain a hole transport layer with a thickness of 40 nm.

In step 4, a solution having CdSe/CdS quantum dots (40 mg/mL) was spin-coated on the hole transport layer at a rotating speed of 1500 rpm and a spin-coating time of 30 s, and then heated at 100° C. for 5 min to obtain a light-emitting layer with a thickness of 40 nm.

In step 5, a solution having ZnO (40 mg/mL) and ethanol was spin-coated on the light-emitting layer at a rotation speed of 3000 rpm for 30 s, and then heated at 100° C. for 5 min to obtain an electron transport layer with a thickness of 20 nm.

In step 6, Ag is evaporated on the electron transport layer by thermal evaporation to obtain a cathode having a thickness of 100 nm, and then epoxy resin encapsulation is performed to obtain a QLED.

The structure of the device was ITO/PEDOT:PSS/P1/QD/ZnO/Ag.

### Device Examples 2-5

Device Example n was basically the same as Device Example 1, except that in Device Example n: when preparing the hole transport layer in step 3, the polymer P1 was changed to the polymer of Example n, n was an integer of 2 to 5, and the polymer of Example n was P2 to P5.

### Device Comparative Examples 1 to 3

Device Comparative Example m was basically the same as Device Example 1, except that in device Comparative Example m: when preparing the hole transport layer in step 3, the polymer P1 was changed to the material of Comparative Example m, m was an integer from 1 to 3, and the materials of Comparative Example m are D1, TFB and PVK in this order.

### Experimental Example

### (1) Hole Mobility and Energy Level Test

Using P1 to P5, D1, TFB and PVK as HTL materials, respectively, and referring to the preparation process of each corresponding film layer in Device Example 1, a detection device having the following structure: ITO/PEDDOT:PSS/polymer/QD/MoOₓ/Ag was constructed. A hole mobility and stability of the materials were then detected by means of a detection device, and the results were shown in Table 1.

The hole mobility of the hole-injected material was recorded by the space charge limiting current (SCLC) method, which may be described by the Mott-Gurney equation: J=9με₀εᵣV²/(8d³).

J is a current density, μ is the hole mobility, ε₀ is the vacuum dielectric constant (8.85×10⁻¹² F/m), εᵣ is the dielectric constant of the material (usually approximately taken as 3 for organic semiconductors), V is the applied bias voltage and d is the film thickness.

TABLE 1

| | hole mobility |
|---|---|
| | (cm² V⁻¹ s⁻¹) |
| P1 | 4.1 × 10⁻³ |
| P2 | 6.2 × 10⁻³ |
| P3 | 8.8 × 10⁻³ |
| P4 | 7.5 × 10⁻³ |
| P5 | 4.8 × 10⁻³ |
| D1 | 5.8 × 10⁻⁴ |
| TFB | 3.6 × 10⁻³ |
| PVK | 2.5 × 10⁻⁶ |

As shown in Table 1:

The hole mobility of the polymer provided by the present disclosure was in the range of 4.1×10⁻³ cm² V⁻¹ s⁻¹˜8.8×10⁻³ cm² V⁻¹ s⁻¹, which was higher than the comparative material without quinoid structure shown in Comparative Example 1, and higher than the commonly used commercial HT materials such as TFB and PVK shown in Comparative Examples 2 and 3, indicating that the polymer proposed by the present disclosure had better hole mobility.

(2) The quantum dot light-emitting diodes of device examples and device comparative examples were subjected to photoelectric efficiency testing and working life testing, and the data are shown in Table 2. Specifically, it includes current efficiency C.E, maximum brightness Lₘₐₓ, measured lifetime T95, and lifetime T95 @1000 nit.

Among them, the test method of maximum brightness Lₘₐₓ and current efficiency C.E is: using Fostar FPD optical characteristic measurement equipment, controlling the efficiency test system built by QE PRO spectrometer, Keithley 2400, and Keithley 6485 through LabView, measuring the voltage, current, brightness, luminescence spectrum and other parameters, and obtaining the current efficiency C.E through calculation.

The test method for lifetime T95 @1000 nit is: the time required for the brightness of the device to decrease to a certain proportion of the highest brightness under constant current or voltage drive. The time for the brightness to decrease to 95% of the highest brightness is defined as T95, and this lifetime is the measured lifetime. In order to shorten the test cycle, the device life test is usually carried out by accelerating device aging at high brightness, and the life at high brightness is obtained by fitting the extended exponential attenuation brightness attenuation fitting formula. For example, the life at 1000 nit is counted as T95 @1000 nit. The specific calculation formula is as follows:

$$T {95}_{L} = T {95}_{H} \cdot {( \frac{{L}_{H}}{{L}_{L}} )}^{A}$$

Among them, T95_{L} is the lifetime at low brightness, T95_{H} is the measured lifetime at high brightness, L_{H} is the device accelerated to the highest brightness, L_{L} is 1000 nit, and A is the acceleration factor. In this experiment, the A value is 1.7 by measuring the lifetime of several groups of QLED devices at rated brightness.

TABLE 2

| | Lₘₐₓ (cd/m²) | T95 | T95@1000nit(h) | C.E(cd/A) |
|---|---|---|---|---|
| Device Example 1 | 9050 | 2.11 | 89.2 | 14.2 |
| Device Example 2 | 9516 | 2.25 | 103.6 | 14.9 |
| Device Example 3 | 10621 | 2.56 | 142.1 | 16.7 |
| Device Example 4 | 10332 | 2.18 | 115.5 | 16.2 |
| Device Example 5 | 9675 | 2.08 | 99.0 | 15.2 |
| Device Comparative Example 1 | 7736 | 1.72 | 55.7 | 12.1 |
| Device Comparative Example 2 | 8252 | 1.86 | 67.2 | 13.0 |
| Device Comparative Example 3 | 4700 | 0.8 | 11.1 | 7.4 |

As shown in Table 2:

Each of device embodiments shows high current efficiency C.Eₘₐₓ, maximum brightness Lₘₐₓ, measured lifetime T95, lifetime T95 @1000 nit, and the lifetime is significantly higher than that of the device comparative examples, indicating that the polymer proposed in the present disclosure may be used as a material of the hole transport layer, and when the hole transport layer is prepared with the polymer, the device has better carrier balance, and macroscopically shows longer lifetime.

The technical solutions provided by the embodiments of the present disclosure have been described in detail above, and the principles and embodiments of the present disclosure have been described herein by applying specific examples, and the description of the above embodiments is only for helping to understand the methods and core ideas of the present disclosure. Meanwhile, those skilled in the field may change the specific embodiments and the scope of application according to the ideas of the present disclosure, and in summary, the contents of the present specification should not be construed as limiting the present disclosure.

What is claimed is:

1. A polymer having a structure of formula (I): 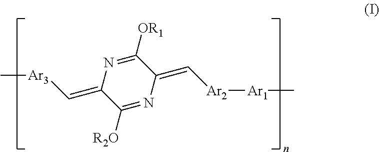
wherein:
n is any integer from 10 to 50;
Ar₁ is selected from any one of the following structures: 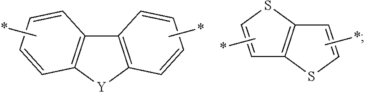
Ar₂ and Ar₃ are each independently selected from any one or more of a substituted or unsubstituted aryl group having 6 to 14 ring atoms, and a substituted or unsubstituted heteroaryl group having 5 to 14 ring atoms;
Y is selected from any one of CR₃R₄, S, NR₅ and O;
R₁, R₂, R₃, R₄, and R₅ are each independently selected from any one or more of H, D, and substituted or unsubstituted C₁-C₃₀ alkyl;
a substituent is selected from one or more of hydroxyl, amino, halogen, carboxyl, nitro, a sulfonic acid group, aldehyde, a thiol group, cyano, C₁-C₅ alkyl, C₁-C₅ alkoxy, and C₁-C₅ alkyl-substituted carbonyl;
* represents site of attachment.

2. The polymer according to claim 1, wherein R₁ and R₂ are each independently selected from C₆-C₂₄ alkyl.

3. The polymer according to claim 2, wherein R₁ and R₂ are the same.

4. The polymer according to claim 1, wherein Ar₂ and Ar₃ are each independently selected from any one of the following structures:

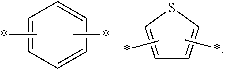

5. The polymer according to claim 4, wherein Ar₂ and Ar₃ are the same.

6. The polymer according to claim 5, wherein Ar₂ and Ar₃ are each independently selected from any one of the following structures:

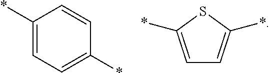

7. The polymer according to claim 1, wherein R₃ and R₄ are each independently selected from C₁-C₈ alkyl;
R₅ is selected from any one or more of H, D, and C₁-C₁₆ alkyl.

8. The polymer according to claim 7, wherein R₃ and R₄ are the same.

9. The polymer according to claim 8, wherein Y is selected from CR₃R₄.

10. The polymer according to claim 1, wherein the polymer comprises one or more of the following structural formulae:

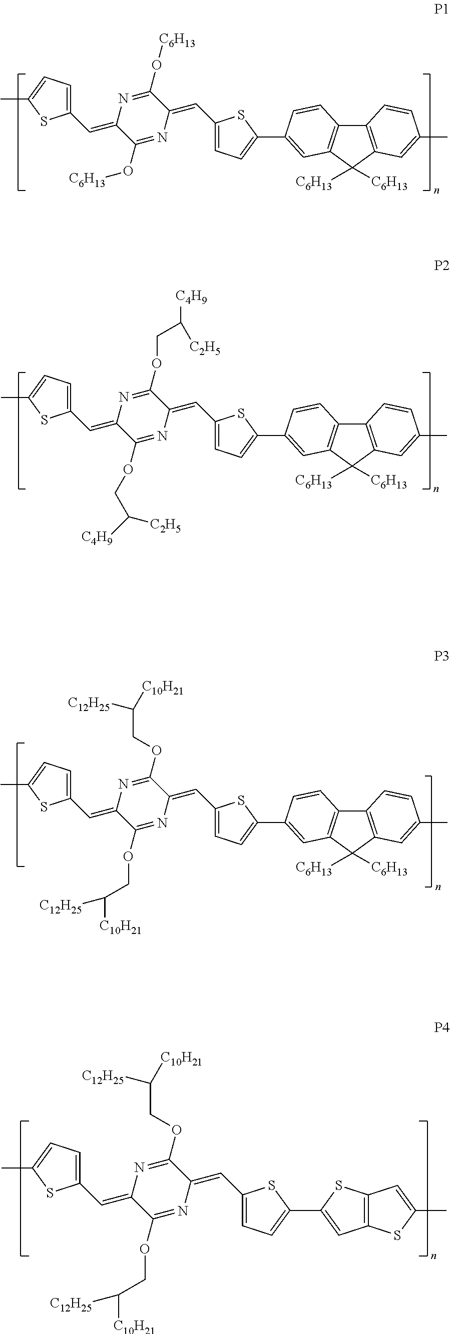

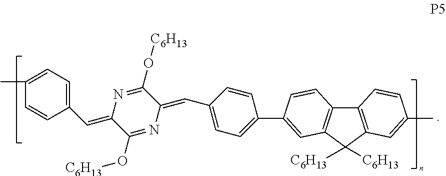

11. A composition comprising a solvent and a polymer having a structure of formula (I): 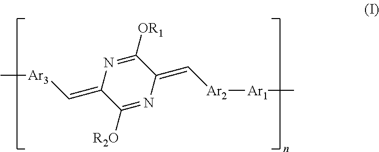
wherein:
n is any integer from 10 to 50;
Ar₁ is selected from any one of the following structures: 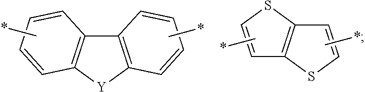
Ar₂ and Arₙ are each independently selected from any one or more of a substituted or unsubstituted aryl group having 6 to 14 ring atoms, and a substituted or unsubstituted heteroaryl group having 5 to 14 ring atoms;
Y is selected from any one of CR₃R₄, S, NR₅ and O;
R₁, R₂, R₃, R₄, and R₅ are each independently selected from any one or more of H, D, and substituted or unsubstituted C₁-C₃₀ alkyl;
a substituent is selected from one or more of hydroxyl, amino, halogen, carboxyl, nitro, a sulfonic acid group, aldehyde, a thiol group, cyano, C₁-C₅ alkyl, C₁-C₅ alkoxy, and C₁-C₅ alkyl-substituted carbonyl;
* represents site of attachment.

12. The composition according to claim 11, wherein a concentration of the polymer in the composition ranges from 5 mg/ml to 30 mg/ml.

13. The composition according to claim 11, wherein the polymer comprises one or more of the following structural formulae:

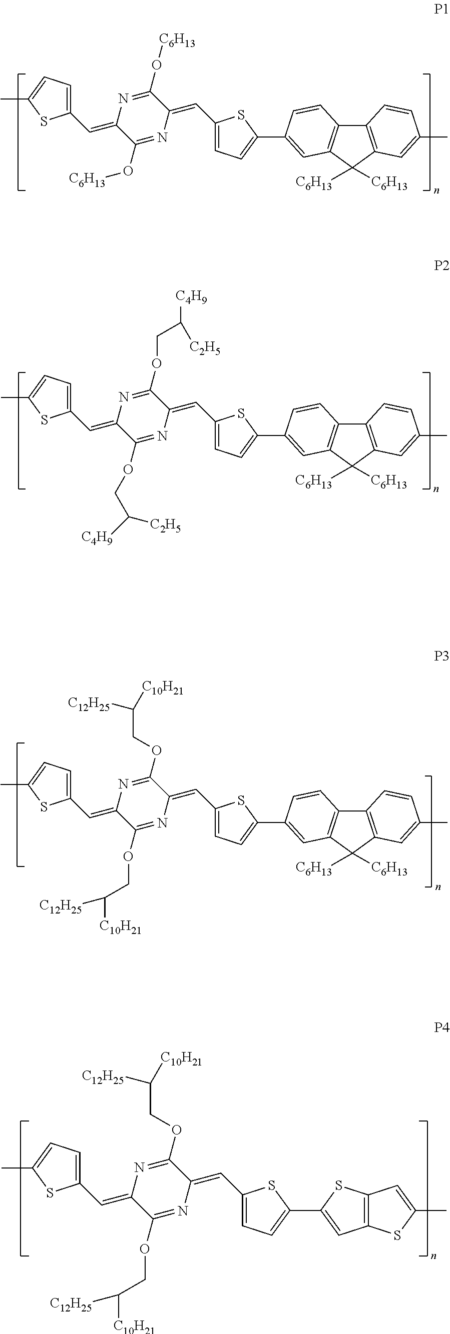

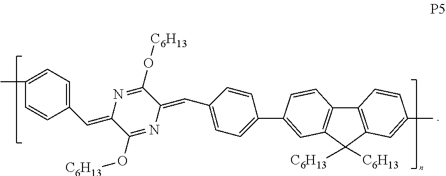

14. The composition according to claim 11, wherein the solvent comprises one or more of chlorobenzene, toluene, xylene, and ortho-dichlorobenzene.

15. An optoelectronic device comprising an anode, a hole functional layer, and a cathode, wherein a material of the hole functional layer comprises a polymer having a structure represented by formula (I): 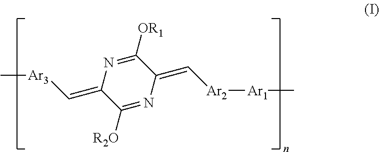
wherein:
n is any integer from 10 to 50;
Ar₁ is selected from any one of the following structures: 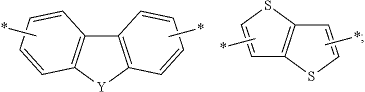
Ar₂ and Ar₃ are each independently selected from any one or more of a substituted or unsubstituted aryl group having 6 to 14 ring atoms, and a substituted or unsubstituted heteroaryl group having 5 to 14 ring atoms;
Y is selected from any one of CR₃R₄, S, NRS and O;
R₁, R₂, R₃, R₄, and R₅ are each independently selected from any one or more of H, D, and substituted or unsubstituted C₁-C₃₀ alkyl;
a substituent is selected from one or more of hydroxyl, amino, halogen, carboxyl, nitro, a sulfonic acid group, aldehyde, a thiol group, cyano, C₁-C₅ alkyl, C₁-C₅ alkoxy, and C₁-C₅ alkyl-substituted carbonyl;
* represents site of attachment.

16. The optoelectronic device according to claim 15, wherein R₁ and R₂ are each independently selected from C₆-C₂₄ alkyl, and R₁ and R₂ are the same;
R₃ and R₄ are each independently selected from C₁-C₈ alkyl, and R₃ and R₄ are the same;
R₅ is selected from any one or more of H, D, and C₁-C₁₆ alkyl;
Ar₂ and Ar₃ are each independently selected from any one of the following structures: 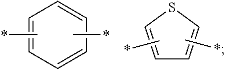
and Ar₂ and Ar₃ are the same.

17. The optoelectronic device according to claim 16, wherein Y is selected from CR₃R₄;
Ar₂ and Ar₃ are each independently selected from any one of the following structures:

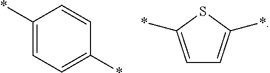

18. The optoelectronic device according to claim 15, wherein the polymer comprises one or more of the following structural formulae:

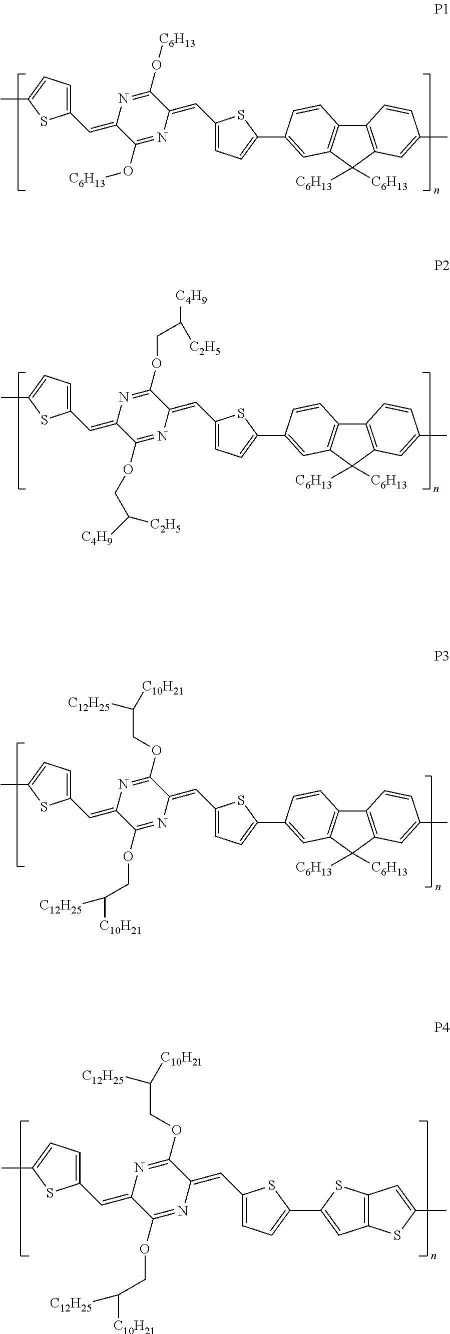

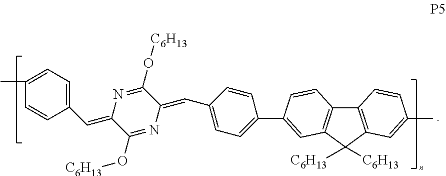

19. The optoelectronic device according to claim 15, wherein the optoelectronic device comprises a light-emitting layer disposed between the cathode and the hole functional layer, and a material of the light-emitting layer is selected from organic light-emitting materials or quantum dot light-emitting materials; the organic light-emitting materials are selected from at least one of the group consisting of a diarylanthracene derivative, a stilbene aromatic derivative, a pyrene derivative, a fluorene derivative, a blue-emitting TBPe fluorescent material, a green-emitting TTPA fluorescent material, an orange-emitting TBRb fluorescent material, and a red-emitting DBP fluorescent material; the quantum dot light-emitting materials are selected from at least one of the group consisting of a single structure quantum dot, a core-shell structure quantum dot, and a perovskite type semiconductor material; a material of the single structure quantum dot, a core material of the core-shell structure quantum dot, and a shell material of the core-shell structure quantum dot are selected from at least one of a Group II-VI compound, a Group IV-VI compound, a Group III-V compound, and a Group I-III-VI compound, and the core-shell structure quantum dot has one or more shell layers; the Group II-VI compound is selected from at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the Group IV-VI compound is selected from at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe; the Group III-V compound is selected from at least one of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb; the Group I-III-VI compound is selected from one or more of CuInS₂, CuInSe₂, and AgInS₂; the perovskite type semiconductor is selected from one of a doped inorganic perovskite type semiconductor, an undoped inorganic perovskite type semiconductor, and an organic-inorganic hybrid perovskite type semiconductor, a general structure formula of the inorganic perovskite type semiconductor is AMX₃, wherein A is Cs+, M is a divalent metal cation selected from one of Pb²⁺, Sn²⁺, Cu²⁺, Ni²⁺, Cd²⁺, Cr²⁺, Mn²⁺, CO²⁺, Fe²⁺, Ge²⁺, Yb²⁺ and Eu²⁺, X is a halogen anion selected from one of Cl⁻, Br⁻, and I⁻; a general structure formula of the organic-inorganic hybrid perovskite type semiconductor is BMX₃, wherein B is an organic amine cation selected from CH₃(CH₂)ₙ₋₂NH₃⁺ (n≥2) or NH₃(CH₂)ₙNH₃²⁺ (n≥2), M is a divalent metal cation selected from one of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, X is a halogen anion selected from one of Cl⁻, Br⁻, and I⁻.

20. The optoelectronic device according to claim 19, wherein the anode and the cathode are each independently selected from a metal electrode, a carbon electrode, a doped or undoped metal oxide electrode, and a composite electrode; wherein a material of the metal electrode is selected from at least one of Al, Ag, Cu, Mo, Au, Ba, Ca, Ni, Ir, and Mg; a material of the carbon electrode is selected from at least one of graphite, carbon nanotubes, graphene, and carbon fibers; a material of the doped or undoped metal oxide electrode is selected from at least one of ITO, FTO, ATO, AZO, GZO, IZO, MZO, ITZO, ICO, AMO, SnO₂, In₂O₃, Cd:ZnO, and Ga:SnO₂; a material of the composite electrode is selected from one of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS and ZnS/Al/ZnS.
